(19) United States
(12) Patent Application Publication
(10) Pub. No.: US 2011/0182324 A1
(43) Pub. Date: Jul. 28, 2011

(54) OPERATING TEMPERATURE MEASUREMENT FOR AN MOS POWER COMPONENT, AND MOS COMPONENT FOR CARRYING OUT THE METHOD

(75) Inventors: Michael Stoisiek, Erlangen (DE); Michael Gross, Erlangen (DE)

(73) Assignee: X-Fab Semiconductor Foundries AG

(21) Appl. No.: 12/993,559

(22) PCT Filed: May 19, 2009
(86) PCT No.: PCT/EP09/56070

§ 371 Date: Apr. 14, 2011

(30) Foreign Application Priority Data
May 19, 2008 (DE) 102008023215.7
May 19, 2008 (DE) 102008023216.5
May 19, 2008 (DE) 102008023217.3

(51) Int. Cl. G01K 7/26; H01L 23/58

(52) U.S. Cl. 374/185; 257/48; 257/E23.002; 374/E07.018

(57) ABSTRACT

The invention is intended to specify an electrical measuring method for an operating temperature and a modified component for carrying out the method which improves the monitoring of the component. Measured temperature values are intended to be delivered without any time delay and without requiring additional surfaces for temperature sensors. Location-related temperature values need to be able to be measured. The invention proposes a method for said location-related electrical measurement of the operating temperature of a likewise proposed MOS power component with a gate electrode network comprising a material whose temperature coefficient of the electrical resistance is known. The gate electrode network is divided into a plurality of measuring sections with contact point pairs which are respectively connected to contacts (71.1, 72.1; 71.2, 72.2; 71.3, 7; 72.3, 7). The contact points in each contact point pair are at a certain distance from one another, and each of the measuring sections situated between the contact point pairs is respectively electrically insulated from the other measuring sections, so that there is no electrical influencing between the measuring sections. The electrical resistances of the measuring sections are measured directly on the gate electrode network during the operation of the semiconductor power component when gate voltages are applied between the contact points of the gate electrode (4) using measuring voltages (u₁, u₂, u₃) superimposed on the gate voltages. The electrical resistances of the measuring sections are used to determine the temperatures of the MOS semiconductor power component on the measuring sections.

The invention relates to a method for measuring the operating temperature of MOS (semiconductor) power components such as e.g. an MOS power transistor or an IGBT and to components for carrying out the method.

The invention relates in particular to semiconductor power components with a transistor cell and to those consisting of a plurality of identical individual cells connected in parallel, in which the total surface of the component is large as compared with the surface of the individual cell and the active surface of the semiconductor chip can be subdivided into individual parts of the gate electrode network, which are electrically insulated from each other, the corresponding component being provided with additional electrical gate contacts for carrying out the method.

Furthermore, the invention relates both to semiconductor power components with a vertical current flow through the semiconductor chip and to components to be integrated in a so-called smart power IC with lateral flow of the main current and comes into consideration for use in components made of the semiconductor material silicon, but also those made of other semiconductor materials such as e.g. silicon carbide (SiC), in that case there being in each case an additional electrical contact per component. For carrying out the method the temperature of the component is measured integrally or in individual surface elements of the component chip during operation of the component. On the one hand, it is ensured with this that no premature failure of the components due to overload takes place, and, on the other hand, the conceivable performance of the component can be better utilized.

An operation of the semiconductor elements near the upper temperature limit of e.g. 150° C. to 200° C. depending upon the type of the component and the stage of development, which is set by the reliability of the component and the observing of the characteristics of the component is desirable. The heat developing during operation due to the transformed electrical power loss must be removed. The operation at the upper temperature limit being basically fixed by the construction of the component and its observance are mostly only possible to a limited extent, since, due to inhomogeneous heat removal properties and/or an inhomogeneous electrical activation of the component, an inhomogeneous temperature distribution across the surface of the component with local temperature peaks, so-called hot spots, is created. The temperature of the hot spots may be possibly increased in an uncontrolled fashion so that the component may be destroyed due to a thermal/electrical regenerative feedback. This thermal limit load is of special importance in the case of a periodic or single operation of the component near the electrical and thermal load limits such as e.g. the unclamped switching off of an inductive load or the switching off of the component after the occurrence of a short circuit of the load.

There are several ways for solving the problem of the safe component operation and for preventing a destruction

One way is the “calculation in advance” and/or the direct measurement of the temperature development as a function of the dissipated power loss and the indication of a transient thermal resistance by means of which the chip temperatures occurring in the current area could be calculated, which, however, entails extensive speculations and a high degree of uncertainty. Since here an indication or calculation based on the entire surface of the component chip is concerned, different temperatures within the surface of the component chip cannot be described (better: modeled) and the occurrence of hot spots cannot be avoided.

Another possibility is the measurement of the temperature occurring during the operation of the component by means of a temperature sensor, which, for this purpose, is expressly integrated in the component or the direct environment of the component, e.g. a p-n junction operated in the forward direction as this is revealed, cf. Khemka et al., “Detection and Optimization of Temperature Distribution Across Large Area Power MOSFETs to Improve Energy Capability”, IEEE Transactions on Electron Devices, vol. 51, No. 6, 1025-1032, 2004, likewise Glavanovics and H. Zitta, “Dynamic Hot Spot Temperature Sensing in Smart Power Switches”, ESSCIRC 2002, 295-298, 2002.

The disadvantage of this method is that the temperature can only be measured at the site of such a sensor and that the number of the sensors to be integrated is limited due to their taking up chip surface. Moreover, there is a minimum distance between the temperature sensor and the adjacent active surface of the component, which is induced by design technology and which results in that the temperature measured at the site of the component and the temperature in the adjacent active chip area deviate from each other and a time-related change in temperature of the active chip area is only measured at the sensor with a considerable delay.

In many cases, in particular if the active area of the component is surrounded by a chip area which is not electrically active, but contributes to heat removal, hot spots centered in the middle of the surface of the component develop. A known method for avoiding these hot spots consists in that the active cells, e.g. of a vertical power MOSFET, which are located in the center of the component are provided with a higher value of the turn-on resistance than the cells of the peripheral chip areas due to the layout, as this is known from Khemka et al., “Detection and Optimization of Temperature Distribution Across Large Area Power MOSFETs to Improve Energy Capability”, IEEE Transactions on Electron Devices, vol. 51, No. 6, 1025 to 1032, 2004. Thus, a specific value is then given by the design, specific safety limits also having to be observed, which also results in a specific performance reduction and does not involve any control possibility.

A temperature sensor for an MOS circuit is known from DE 102 20 587 B4 and the corresponding U.S. Pat. No. 6,948,847 B2, the content of which, however, is enlarged, the temperature sensor having at least one MOS transistor, in which a voltage drop between a gate input and a gate output is determined by means of a gate means. The gate means is split up into individual gates, which are only partly electrically connected between the gate input and the gate output. This arrangement is designed for the temperature measurement of the ambient temperature and the influence of the temperature of the component itself is not taken into consideration, but ignored.

The purpose of the invention is to increase the accuracy and speed of the reaction time of counter-measures, e.g. against an also partly overheating of the MOS semiconductor component, during the measurement of the temperature of the semiconductor chip during an operation of the MOS semiconductor component and to thus increase the reliability.

The invention is based on the object of indicating an electrical measuring method for the operating temperature and a modified component for carrying out the method, which improves the monitoring of the component. Measured temperature values are to be supplied without time delay without requiring additional surfaces for temperature sensors which have to supply site-related temperature values.

According to one aspect of the invention a method for the measurement of the operating temperature of an MOS semiconductor power component with a gate electrode made of a material is indicated, whose temperature coefficient of the electrical resistance is known. Here, the gate electrode has two contact points arranged on the gate electrode at a specific (or: defined) distance, between which an unequivocal measuring section is defined. The electrical resistance along the unequivocal measuring section between the contact points is measured during the operation (naturally directly with or along a section) of the gate electrode—with applied gate voltage for the operation of the power component—with a measuring voltage superimposed on the gate voltage. The operating temperature of the MOS power component is determined from the measured electrical resistance by means of the known temperature coefficient.

Here, the gate electrode may be subdivided into several measuring sections between respective contact points, which are connected in each case with a strip conductor. Here, each pair of contact points has a specific distance on the gate electrode and a specific section of the gate electrode between it to form a respective measuring section.

Moreover, it is advantageous if the respective measuring section would be defined by the fact that at least one separating point interrupts other conductive paths along the gate electrode (for the electrical insulation or better: “setting free” of the measuring section. Thus, it becomes an unequivocal measuring section which is not composed of parallel paths in its (total) resistance.

According to a further aspect of the invention the method for the (site-related) electrical measurement of the operating temperature of an MOS semiconductor power component with a gate electrode network made of a material is indicated, whose temperature coefficient of the electrical resistance is known, the gate electrode network being subdivided into several measuring sections with pairs of contact points which are in each case connected with contacts, the contact points of each pair of contacts having a specific distance and the measuring sections located between the pairs of contact points being in each case electrically insulated from the other measuring sections so that no electrical influencing between the measuring sections is given, the electrical resistances at the measuring sections being directly measured at the gate electrode network during the operation of the semiconductor power component with applied gate voltages between the contact points of the gate electrode by means of the measuring voltages superimposing by the gate voltages, the temperature of the MOS semiconductor component being determined at the respective measuring sections from the electrical resistances of the measuring sections

Here, it is advantageous if the measuring sections are defined by the fact that at least one separating point (there may also be several ones) interrupt other conductive paths along the gate electrode for the “electrical insulation” of the measuring sections.

Here, it is furthermore advantageous s if an MOS power component is concerned which consists of a plurality of individual cells being equally structured in functional respect.

It is furthermore advantageous if the MOS power component is a component of an integrated circuit and the temperature detection and evaluation of the at least one temperature measuring section and a supplying of power to the component is automatically implemented by means of a corresponding circuit as a component of the integrated circuit (claim 12).

Here, it is furthermore advantageous if the pairs of contact points are distributed across the surface of the component in such a way that an allocation of individual temperatures to specific surface portions of the total surface of the component can be designed as a “temperature distribution” across the total surface of the component.

It is apparent in the aforementioned methods that they can be carried out without the presence of an additional temperature sensor, which is especially designed for this and takes up chip surface.

It is furthermore advantageous in the aforementioned methods and/or components if an a-c voltage is applied as the measuring voltage.

It should be mentioned that the applied voltage is also formed by impressing, for instance, a constant current, i.e. it may be caused by the current source. Then, the voltage formed is an image of the temperature-dependent resistance.

According to a further aspect of the invention a semiconductor power component is made available for the electrical measurement of the temperature-dependent resistance of a gate electrode during the operation for the purpose of temperature control. In addition to a first strip conductor to a first contact point on the gate electrode, an additional strip conductor at least to a further contact point of the gate electrode of the MOS semiconductor power component is present on the gate electrode so that a specific distance of the (two) contact points on the gate electrode is determined. A measuring section of the gate electrode between a first contact point and a further contact point is formed in this fashion.

This measuring section may be insulated from other parts of the gate electrode in the sense of its unequivocalness or its being uninfluenced by other conductive paths of the gate electrode.

Here, it is advantageous if the gate electrode is subdivided into several measuring sections with contact points which are in each case connected to a strip conductor, the contact points of a respective pair of contact points having a specific distance.

Here, it is furthermore of advantage if the measuring section is defined by the fact that at least one separating point interrupts other conductive paths along the gate electrode (for the “electrical insulation” of the measuring section).

Here, it is furthermore of advantage if a discrete MOS power component is concerned.

According to a further aspect of the invention (claim 18) a semiconductor power component which consists of a plurality of individual cells having (functionally) the same structure with a gate electrode network is made available for the site-related electrical measurement of the temperature-dependent resistance of the gate electrode during the active operation of the component. Several additional contact points on the gate electrode network, which form pairs, are present with forwarding contacts, which are distributed on different (non-overlapping) partial areas of the gate electrode of the semiconductor power component. The contact points of a respective pair of contact points have a specific distance from each other (or: resistance between each other), due to which a specific measuring section is in each case defined and the various defined measuring sections of the pairs of contact points are electrically insulated from each other by means of separating points.

Here, it is furthermore of advantage if several partial sections of the gate electrode which are mutually electrically insulated are present, which have in each case contacts attaching at their ends at contact points (or: strip conductors adjoining them).

Here, it is furthermore advantageous if the measuring sections are distributed across the surface of the component in such a way that an allocation of individual temperatures to specific surface portions of the total surface of the component is given as the temperature distribution across the surface of the component.

According to a further aspect of the invention a semiconductor power component consisting of a plurality of individual cells having (functionally) the same structure and in which several of the individual cells together form in each case a partial area of the component is made available, which has a gate connection of its own, which is common to the cells of the partial area and is electrically insulated with respect to the gate electrodes of other partial areas. This serves for measuring several temperature-dependent resistances of the gate electrode for the purpose of the determination of the temperature of each partial area as the temperature distribution during operation. At least one pair of contact points of the gate electrode of the MOS power component with corresponding contacts (includes feed lines) is present in each partial area of the semiconductor power component, the contact points of a pair of contact points having a specific distance from each other. Due to this a specific measuring section is defined in each case and due to the presence of several of such measuring sections in partial areas of the component the measuring sections of the pairs of contact points are electrically independent (or: insulated from each other by separating points).

Here it is furthermore of advantage if the measuring sections are distributed across the surface of the component in such a way that an allocation of possibly different area temperatures to specific surface portions of the total surface of the component is given.

According to a further invention (claim 27) the semiconductor power component has a plurality of parallel individual cells of the same functional structure. Several ones of the plurality of individual cells together form a partial area of the power component in each case, each partial area as an area having a gate connection of its own being common to the cells of the partial area so that several areas with several gate connections are formed. Gate electrodes of the (or in the) partial areas are electrically insulated from each other by separating points for measuring a temperature-dependent resistance of each of the gate electrodes during the operation of the power component. A determination of a temperature distribution can be implemented on the basis of this. At least one pair of contact points is present on the gate electrode of the partial area of the MOS power component in each of the partial areas of the semiconductor power component and the same are accessible from the outside in an electrically conductive fashion with appertaining feed lines and contacts. The contact points of a respective pair of contact points have a specific distance from each other, due to which an unequivocal measuring section is defined in each case for measuring a temperature-dependent resistance.

This structure (claim 27) also enables a measuring method (claim 21).

The aforementioned aspects and the advantageous developments have the advantages that the operating temperatures can be measured accurately, near the site (close to the site of the generation is meant) and with a negligible time delay. The formation of hot spots can be recognized more rapidly and a failure of the component can be better prevented. Thus, the reliability of the component is improved.

The temperature-dependent electrical resistance of the gate electrode or of the anyhow present gate electrode network is measured during the operation of the component and used for determining the current temperature of the component at the measuring site with known temperature coefficient of the resistance of the gate electrode material. This is a site-related measurement.

The gate electrode network which is usually only provided with one contact is provided with at least one additional contact for the measurement of the resistance. A site-resolved detection of several temperatures is carried out by means of several ones of such additional contactings of the gate electrode network so that a temperature can be determined in the component area between these two contacts between respectively two, in particular adjacent contacts by means of the measurement of the resistance. For this purpose, the gate electrode and/or the gate electrode network may be subdivided into segments being insulated from each other (or better: independent segments) which then can be measured independently from each other (or: in each case independently) without parasitic induction.

This procedure can basically be used in all gate electrode materials with a suitable temperature coefficient of the resistance such as e.g. polysilicon. Since the gate electrode is largely only thermally coupled to the subjacent silicon via a thin gate oxide, the measured gate electrode temperature represents a good measure for the temperature of the subjacent silicon. Moreover, the temperature of the gate electrode follows a change in temperature in the subjacent silicon with only a very small delay due to this.

Due to the positioning of the additional gate contacts there is a very extensive flexibility as regards the extension and position of the component area covered by the temperature measurement. The mean temperature of selected surface segments of the component can be determined with contacts lying far apart, e.g. the temperature in concentric annular or polygonal, in particular square segments (i.e.: areas) of the component surface. On the other hand, a resistance and thus the temperature can be determined with a high site resolution due to the gate contacts being very close to each other.

Since the measuring voltage may be selected small as compared with the gate voltage in the component activated during operation for determining the gate resistance, the measurement of the gate resistance is possible by means of an auxiliary voltage (or auxiliary current) and thus during the operation of the component.

With associated activation and signal evaluation circuits d-c voltage or a-c voltage may be used as a probe for the resistance measurement. Here, measurements of the a-c voltage (or such current measurements) have the advantage of the greater sensitivity and better uncoupling of the resistance measurement and due to the temperature measurement of the “primary” gate activation (that for the operational activation).

The invention is explained by means of several examples with the aid of the schematic drawing, wherein:

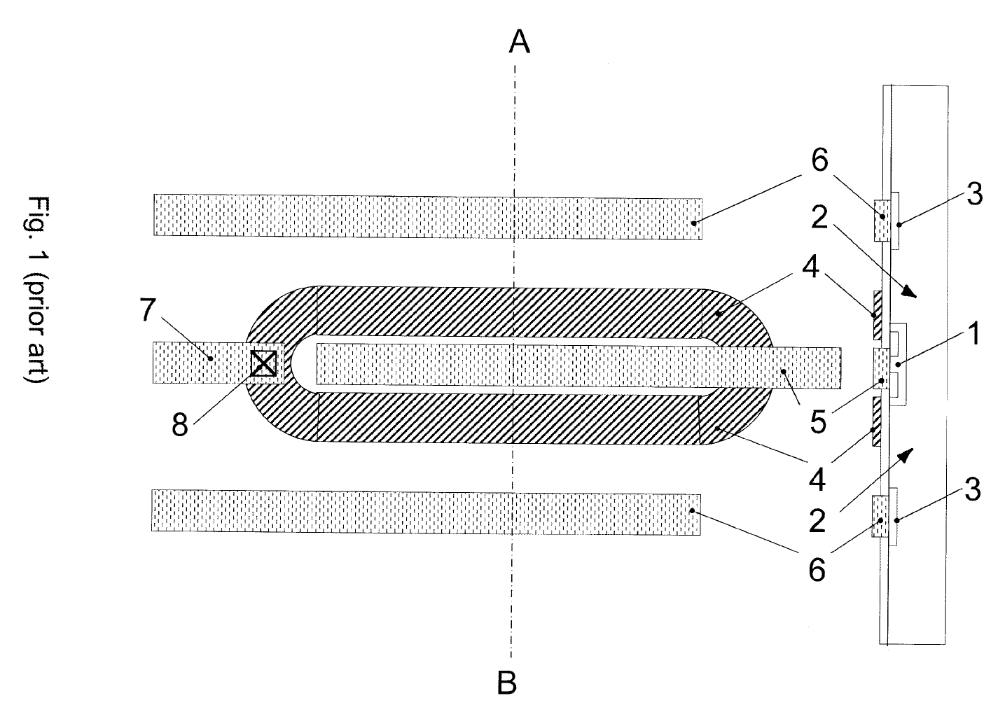

FIG. 1 shows a top view of and a section through a conventional one-finger MOS transistor with source body contact 1 located in the center and two drift zones 2 being symmetrically arranged with respect to it, which corresponds to the prior art;

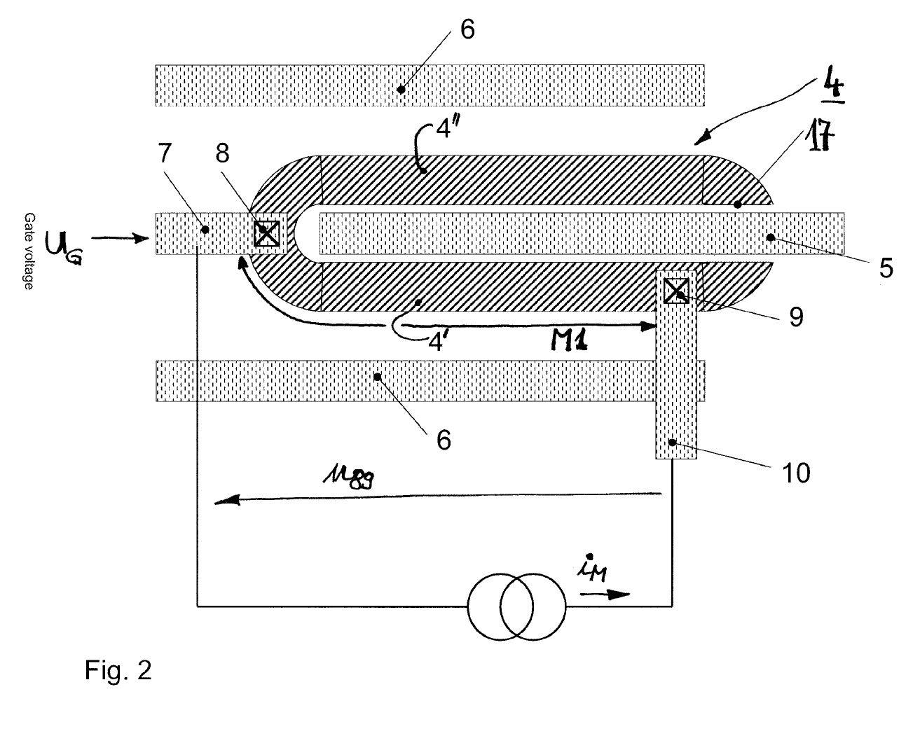

FIG. 2 shows an MOS transistor modified for an example of an MOS transistor modified according to a method according to the invention, i.e. provided with an additional gate contact 9 and a separating point 17, which otherwise has the same structure as in FIG. 1;

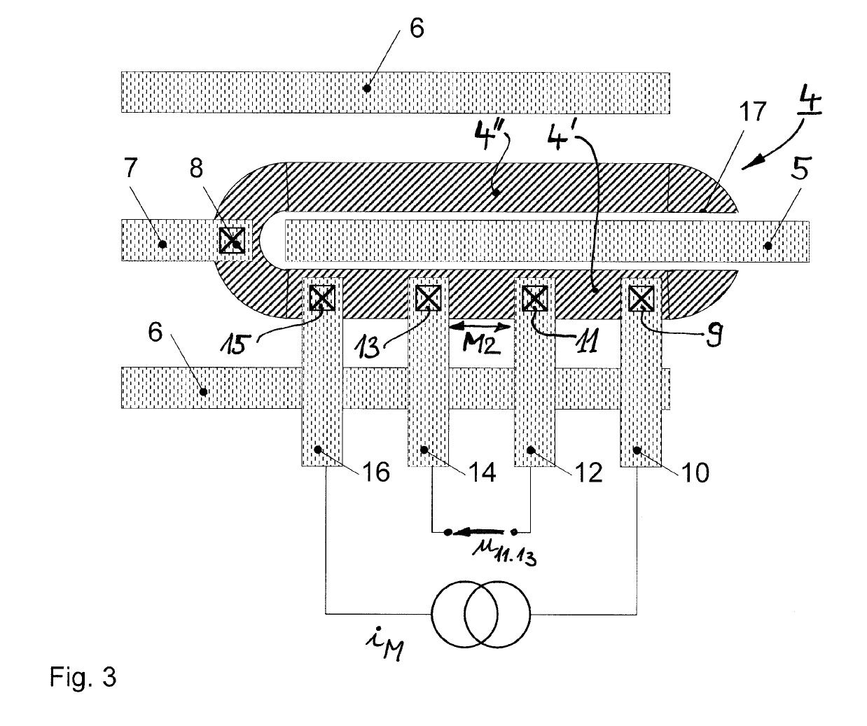

FIG. 3 shows a further example of an MOS transistor according to the invention, which is provided with several additional gate contacts 9 to 15 and otherwise has the same structure as in FIG. 2;

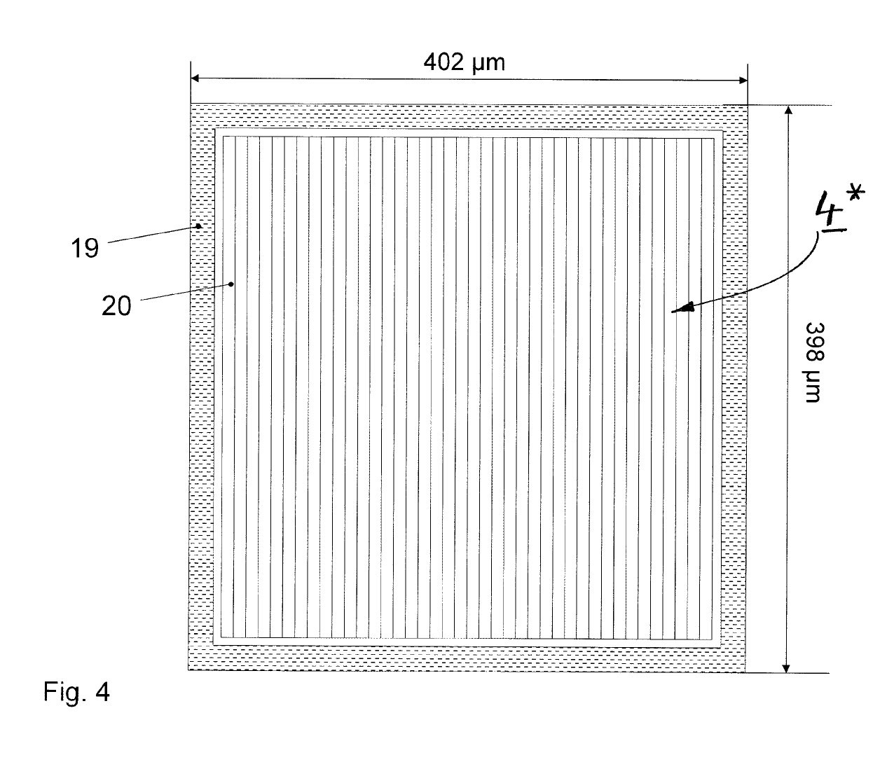

FIG. 4 shows a top view of an MOS transistor with a real surface size of approx. 0.4 mm×0.4 mm, which consists of a plurality of identical finger-shaped individual cells 20 which are vertically disposed and which extend in a side-by-side relationship (in parallel), 19 being a marginal area outside the gate network 4*;

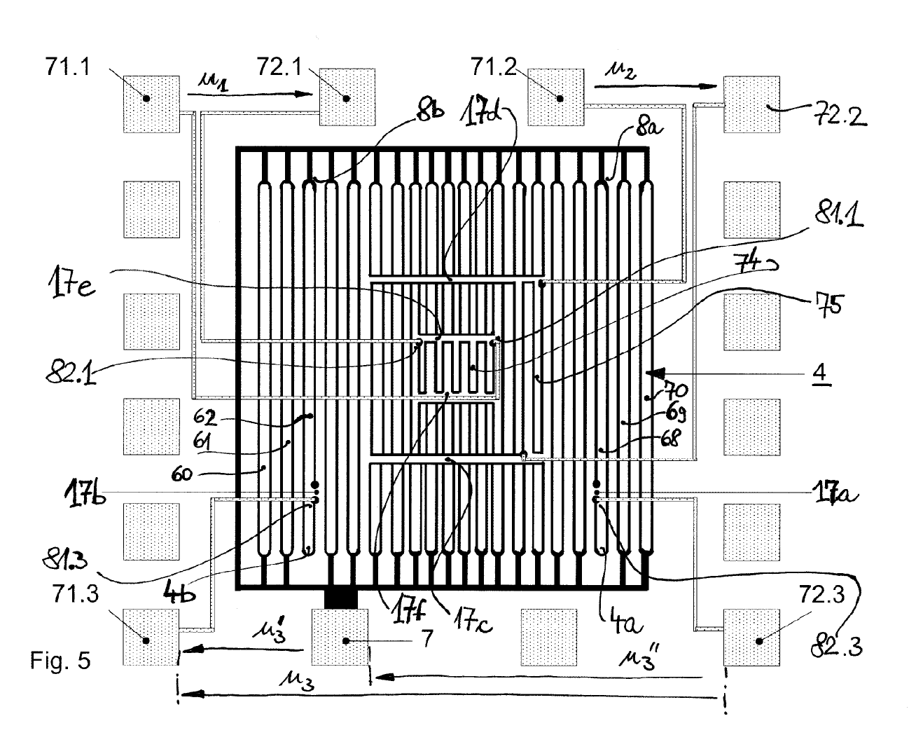

FIG. 5 shows a system of gate connections and contacts of a further example of an MOS transistor according to the invention with a comparable basic structure as in FIG. 4 and with additional gate contacts and a modified gate network 4;

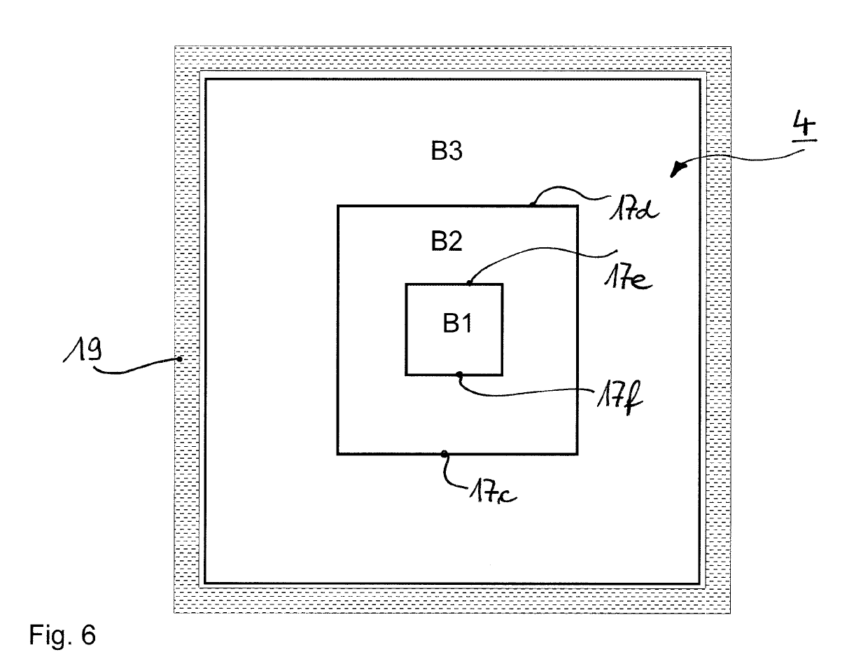

FIG. 6 shows the systematic division of the MOS transistor shown in FIG. 5 into three concentrically disposed areas B1, B2, B3, which can be separately detected as regards temperature measurements by the additional gate contacts according to FIG. 5;

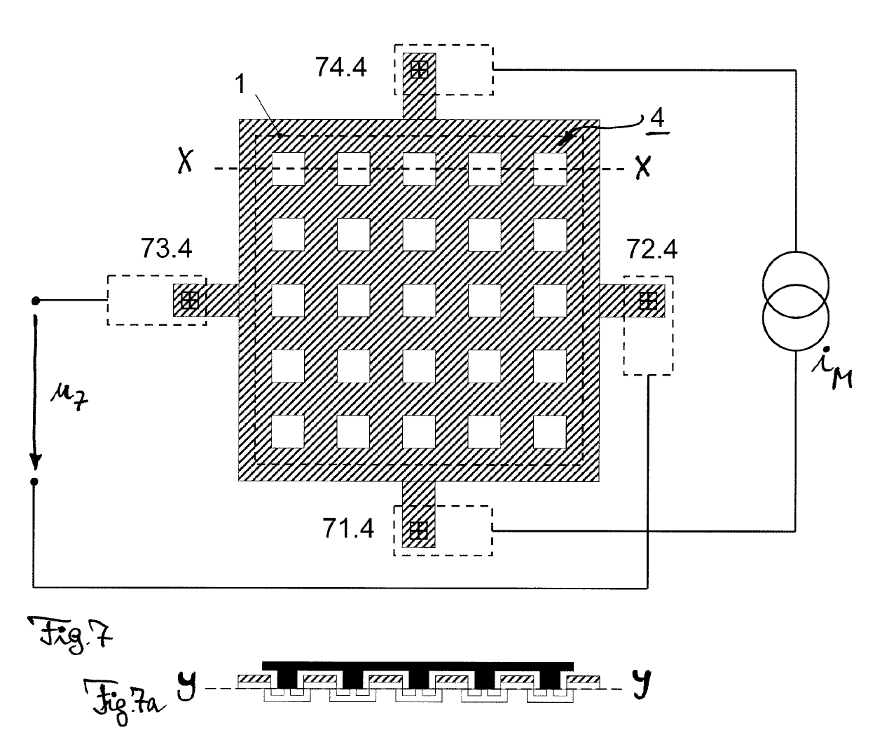

FIG. 7 and

FIG. 7a show a top view of and a section through an MOS transistor as a further example of the invention with square individual cells, which are connected in series.

FIG. 1 shows a top view of a conventional elongated one-finger transistor with the source body complex 1 located in the center and two drift zones 2 and drift zones 3 being disposed symmetrically thereto on the left-hand and on the right-hand sides. The gate electrode 4 in the form of a stretched circular ring and metallic strip conductors 5, 6 for contacting the source area 1 and the drain areas 3 and a conductive path 7 (also: strip conductor as an electrically conductive path) to a contact point 8 on the gate electrode 4 are plotted in the schematic arrangement. Moreover, the Fig. shows the typical doping zones and layer sequences of material along a section A-B.

An MOS transistor modified as compared with the transistor of FIG. 1 is shown in FIG. 2. The annular gate electrode has an additional contact point 9 and a strip conductor 10 connected thereto. Now the gate electrode resistance between the contact points 8 and 9 can be measured between the strip conductor 7 to the contact point 8 on the gate electrode 4 and the strip conductor 10 within the framework of a two-point measurement and, thus, the temperature in this area can also be indirectly measured.

So that the measurement of the resistance only relates to the connection 4′ (as measuring section M1) between the contact points 8 and 9, which is located at the bottom in the Fig., the second possible current-bearing connection 4″ is interrupted by a separating point 17. The measurement of the gate electrode resistance with a two-point measurement is possible, if the resistance of the strip conductors 7 and 10 is negligibly small as compared with the resistance of the section 4 of the gate electrode 4′, which is to be measured.

The measurement is carried out as illustrated in FIG. 2. A preferably constant current i_{M} is fed between the contact points 8 and 9 on the plotted measuring section M1. On the assumption that the strip conductors 7 and 10 do not contribute any essential share to the resistance of the measuring section M1, the resistance can be calculated at these strip conductors by means of a voltage measurement. In the case of a known temperature coefficient of the electrical resistance the temperature can be determined from it. Here, the temperature relates to a mean temperature along the measuring section M1.

Since the gate electrode is largely thermally coupled to the subjacent silicon only via a thin gate oxide, the measured temperature of the gate electrode represents a good measure for the temperature of the subjacent silicon. Moreover, the temperature of the gate electrode follows a change in temperature in the subjacent silicon with only a very small delay.

The measured voltage is symbolically represented with u₈₉ and follows from the impressed current i_{M}. If the other measurement which is not plotted is selected, a voltage must be applied from which a current to be measured ensues depending upon the resistance along the measuring section M1, i.e. between the contact points 8, 9. A change in the resistance caused by a change in the temperature in the area along the measuring section M1 (regarded as an average) changes the measured current so that a resistance can be ascertained the voltage being known, which permits a directly calculable conclusion to the temperature of this section by means of the temperature coefficient. Thus, the temperature of the MOS semiconductor power component which is schematically represented in FIG. 2 is determined from the electrical resistance.

This determination of the temperature takes place during the operation of the MOS component, which is symbolized by means of the indication of the gate voltage. This gate voltage U_{G} activates the gate in potential respect via the one strip conductor 7 and the contact point 8 and thus controls the transistor on-state or off-state (locking or non-locking) and the measuring voltage which was explained above and is symbolically represented with u₈₉ is superimposed on this gate voltage

This superimposition is effected via an impressed current or via an impressed voltage and may be present as am a-c value or d-c value, i.e. direct current or alternating current, d-c voltage or a-c voltage. This general representation is to be conceptually paraphrased by the d-c magnitude or a-c magnitude, which causes that the resistance along the measuring section M1 or, in different words, the resistance between the contact points 8 and 9 can be measured. The temperature of the measuring section M1 is measured from the measured resistance by means of said conversion.

If the resistance of the strip conductors 7, 10 is not negligibly small as compared with the resistance of the gate electrode 4 along the measuring section, which is to be measured, the measurement can be carried out with a four-point method with independent contacts for the feed of the measuring current and the voltage measurement. An MOS transistor provided with several additional gate contacts is shown in the appertaining FIG. 3, which otherwise has the same structure as the MOS transistor in FIG. 2 and which is suitable for the resistance measurement with a four-point method with independent contacts for the feed of the measuring current and the voltage measurement.

With changed electrical connections and a further separating point or insulation (not represented) amidst the four additional gate contacts the transistor is suitable for a temperature measurement which is site-resolved on the repeatedly contacted branch of the gate electrode.

This embodiment variant of the MOS transistor has several additional gate contacts 10, 12, 14, 16 for the four-point measurement of the gate electrode section located between the contact points 11 and 13.

In the case of the use of the two-point measurement the resistance between optionally selectable contact points of the gate electrode can be measured, e.g. between the contact points 8 and 15, between the contact points 15 and 13 or also between 15 and 9 and thus the mean temperature of the area enclosed by the contact points can be determined. In the case of the presence of further separating points of the gate electrode, which are not shown, e.g. between the contact points 8 and 15 and 13 and 11, two electrically insulated sections of the gate electrode being formed, the operating temperature can be measured in the smaller adjacent sections of the gate electrode independently of each other.

The measurements described above with a-c magnitudes or d-c magnitudes can also be applied to FIG. 3 and are symbolically plotted here. The plotted situation is that of the four-point measurement and the feeding of a measuring current i_{M} to and through the contact points 15 and 9. The measurement itself is carried out on the contact points 11 and 13 which are located further inwards and results in the voltage u_{11.13} measured along this measuring section M2 between these two contact points and depending on the current and the temperature of the measuring section M2.

If used accordingly the shown example is also possible with the other measurements between other contact points as explained above and can be transferred to them.

It should be mentioned that an unequivocal path, i.e. an unequivocal measuring section, exists between two contact points through the opening of the electrical gate path at the separating point 17 so that an unequivocal statement on the temperature and the site of the temperature can be given.

An example of a further development of a large-surface MOS power transistor consisting of a plurality of parallel individual cells is represented in FIGS. 4, 5 and 6. The transistor chip is represented in a square form with a side length of approx. 0.4 mm in FIG. 4. The active inner area is taken up by a large number of identical finger-shaped individual cells 20 in accordance with FIG. 1, which are arranged in a side-by-side relationship. Only the gate electrode paths of a gate electrode network 4* which is schematically represented as being present and which is located above the individual cells 20 according to FIG. 4 differ from each other in various areas of the MOS power transistor according to the following explanations and representations regarding the formation of the new gate network 4.

The plurality of the activated individual cells form the power component. They have the same function. The gate electrode network 4* shown in FIG. 4 is segmented according to the following representations and thus it does no longer have the same structure, but—based on all segments—it still only has the same function.

The example shown in FIG. 5 distinguishes itself in that the surface of the component is taken up by finger-shaped parallel individual cells and the gate electrode network 4 consists of strips located side by side or elongated annular paths 60 to 70, which are segmented by separating points.

The gate electrode paths of the gate electron network, which are located side by side, are only partly connected to the common gate contact 7 in accordance with the diagram of FIG. 5 and are partly provided with additional contacts 71.1 and 72.1 or 71.2 and 72.2 or 71.3 and 72.3. Moreover, gate electrode paths which were originally coherent, e.g. the gate electrode paths 4a, 4b, are partly interrupted by separating points 17a, 17b, due to which specific sections of the gate electrode result, which are mutually electrically insulated at their ends. They have one contact point at one of their ends each, e.g. a third contact point 72.3 and/or 71.3, with an additional strip conductor each and an additional gate contact each.

The additional gate contacts 71.1, 72.1 reach e.g. a first pair of contact points 81.1 and 82.1, the gate contacts 71.1, 72.1 being connected with a meander-shaped gate electrode path 74 via additional strip conductors, which forms an inner measuring section which is separated by separating points 17e, 17f by adjacent gate electrode paths and thus insulated. The separating points 17e, 17f are strip-shaped and extend transversely to the gate electrode paths that are vertically disposed.

The additional gate contacts 71.2, 72.2 lead to a second pair of contact points, these gate contacts 712, 72.2 being connected with a gate electrode path 75 which is (initially) meander-shaped via additional strip conductors, which forms a further measuring section and is separated from the adjacent gate electrode paths by further separating points 17c, 17d and thus insulated. The further measuring section is located between the outer area B1 and the inner area B3, cf. in this connection FIG. 6.

These three areas from FIG. 6, the inner area B1, the intermediate area B2 and the outer area B3, are concentric. Here, they have a square shape, which, however, must not be considered as a general concept, but as a result of the example illustrated here. The separating points which were explained above extend horizontally (transversely to the longitudinal extension of the conductive strips 60 to 70 which are located side by side or the elongated conductive annular paths) and insulate the elongated paths in the area of B3 with respect to the area B2. The paths in the area B2 are electrically insulated from the area B1. Then the area B1 is naturally also electrically insulated from the area B3. “Separating points” that extend longitudinally are no separating points which were separately inserted, but they result from the distance of the strips, which, naturally, represents an insulating area between two parallel paths of the gate network, which extend longitudinally.

The paths of the gate electrode network extend in a fashion clearly deviating from FIG. 4 within the areas B1 and B2, which only schematically shows paths of a network 4 for a uniform gate, which are basically longitudinally stretched and extend in parallel, which is illustrated more precisely in examples of the invention and is shown here in a specific example in FIG. 5.

All three areas B1, B2 and B2 are functionally equal, but as regards the precise gate structure of the network in a respective area they are structurally different.

Thus, the inner area B1 is purely meander-shaped between the two contact points 81.1 and 82.1. The central area B2 carries partly, i.e. only at the beginning, a meander between the two contact points consisting of three path sections (which alternately extend upwards and downwards) and is formed as a network extending in parallel in the remaining area in accordance with the structure of strips being purely in parallel or elongated annular paths which, at the top and at the bottom, have a transverse connection each of a conductive nature as this is shown for the outer area B3 more clearly and with thicker lines at the top and at the bottom.

An outer structure connecting as regards the potential with fingers being respectively short at the top and at the bottom is formed as a conductive structure in the outer area B3, which connects the network consisting of the elongated strips or elongated annular paths at the top and at the bottom. These elongated strips or annular paths of the gate network are e.g. made of polysilicon.

The separating points 17d, 17c which insulate the outer area B3 and the intermediate area B2 from each other are transversely extending in a strip-shaped fashion.

The gate electrode network of the outer area B2 ends in the central area in the separating points 17d, 17c extending transversely, e.g. at metallic conductors extending transversely, or it may also be designed with strip ends remaining free. The intermediate area B2 largely ends at the top and at the bottom in a comparable fashion with the exception of the meander portion 75. And this also with connection conductors which are located at the top and at the bottom and extend transversely. Only the inner area B1 is excepted from this, with respect to which the transversely extending separating points 17e and 17f form a limit (i.e. an insulation).

The distribution of the additional gate connections and the electrical interruptions of the network of the gate electrode is based on a division of the surface of the component into three concentric areas as the partial areas B1, B2 and B3 according to FIG. 6, in which the temperature can be separately detected in each case by measuring the resistance of each partial area at the respective gate.

All gate electrodes are connected with the common gate connection 7 as paths 60, 61 . . . 70 in the third partial area B3 of FIG. 5. Only one gate electrode path 4a (as 68) each of a finger-shaped cell 20 on the right-hand side of the partial area B3 and one gate electrode path 4b (as 62) each of a finger-shaped cell 20 on the left-hand side of the partial area B3 are additionally contacted by conductors of third gate contacts 72.3 and/or 71.3 for the temperature measurement with the two-point method in the partial area B3 at the edge of the active component chip.

Here, possible measuring sections are located between a contact point 8a (between a strip conductor of the gate contact 7 and the gate electrode path 4a) and a second contact point (between the conductor of the gate contact 72.3 and the gate electrode path 4a), on the one hand, or a contact point 8b (between the strip conductor of the gate contact 7 and the gate electrode path 4b) and a fourth contact point (between a strip conductor of the gate contact 71.3 and the gate electrode path 4b), on the other hand, or the sum of these measuring sections as the formation of the mean value across a greater length of contact point 81.3 to contact point 82.3. The latter combination (connection in series) of the paths 4a and 4b uses the resistance between the gate contacts 71.3 and 72.3.

The use of the contacts 7, 71.3 and 72.3 for the temperature measurement in the area B3 can also be carried out in this fashion.

The temperature measurement in B3 will be carried out for a mean value by means of the measurement of the resistance between 71.3 and 72.3. In this case an averaged information on the resistance and, consequently, a statement on the temperature on the left-hand and the right-hand side of the area B3 are obtained. If the resistance is measured between 71.3 and the contact 7 and/or between 72.3 and the contact 7, the information on the temperature is only obtained on the left-hand side or only on the right-hand side of the area B3.

It is equally good in all measurements of the resistance of a gate segment whether this is done by impressing a known current and measuring the resultant voltage drop or by applying a known voltage and measuring of the resultant current.

Reference is made to the explanation on FIG. 2 for the measurement by means of voltage or current, d-c magnitude or a-c magnitude. The measuring section M1 there is basically present as at least three different measuring sections M_{B1}, M_{B2} and M_{B3} in the three areas B1 to B3, it being possible to design the measuring section M_{B3} in the described three designs, as only a left-hand side, only a right-hand side or the total path may consist of sections of both electrode paths 4b and 4a and/or 62 and 68.

The separating points 17b and 17a in said paths 62 and 68 and/or 4a, 4b are an interruption of the plotted annular path. Due to this, the measuring section is unequivocal. The separating point 17b is “separated” a distance downwards and the entire path is “separated” upwards from the annular path in the plotted situation and the somewhat shorter section above the separating point 17b (right-hand section of the annular path of the Fig.) is not a component of the measuring section. This measuring section reaches from 82.3 to the contact point 8b on the left-hand side of the area B3. The metallic connection conductor to the gate contact 7 is not a component of this resistor. The interruption 17a is provided on the right-hand side of B3 in an accordingly mirror image fashion with respect to the vertical central plane, by means of which the two ends are mutually insulated at the interruption point 17a and an unequivocal measuring section is achieved along the annular path 4a, that is to say of the remaining section of the annular path 4a from the contact point 82.3 to the contact point 8a. The measuring sections can be individually evaluated using the contact 7 or they can be evaluated by means of a series connection.

The measuring paths 4b and 4a are not connected to the network of conductors from the contact 7 to all ends of the other paths at the lower end in FIG. 5. Here, as well, one insulating separating point each is provided.

As regards the measuring method reference is made to FIG. 2. The measuring voltage shown there and the measuring current shown there may be used as a d-c value or a-c value.

The plotted measuring voltages for the third area B3 result from FIG. 5.

The left-hand area can be measured across the path 4b. The appertaining voltage is u₃′. The right-hand section can be measured between the contact 7 and the contact 72.3 with the voltage u₃″. The summed voltage, i.e. the connection in series of these two measuring sections, is measured by means of the voltage u₃ between the contacts 71.3 and 72.3. A voltage was impressed in the case of a resultant voltage. The reverse measuring method according to the description regarding FIG. 2 can be used here, as well.

Accordingly, voltages u₁ result for B1 and u₂ for B2 in each case between the appertaining pair of contacts.

The plurality of individual cells 20 which have functionally the same structure and which can be seen in FIG. 5 and which are connected in parallel and, on the one hand, differ in their gate structure, but, on the other hand, are largely similar, are jointly activated via the gate contact 7 by applying a gate voltage U_{G} in accordance with FIG. 2. The measuring voltage, in the example u₃ for the outer area B3, is superimposed on this gate voltage. Here, the measuring voltage applied or is causally formed by a measuring current which flows through the measuring section and thus generates a voltage drop, on which the gate voltage for the operation and during the operation of the semiconductor power component of FIG. 5 is superimposed.

All gate areas can be independently activated. The gate contact 7 controls the gate area B3. One of the contacts 71.1 and 72.1 can make a voltage available for activating the inner area B1, which can be adjusted or fixed independently of the voltage at the contact 7. One of the two contact points 71.2 and 72.2 may serve for supplying a further independent gate voltage for the area B2 of FIG. 6. This gate voltage, as well, can be adjusted or fixed independently of the other mentioned gate voltages.

Thus, the component has several partial areas and each partial area as an area has a gate connection of its own which is common to the cells of this area or partial area, it being possible to activate the MOS transistor via its potential. All three potentials can naturally also be activated by an equal uniform potential. If they are activated by different potentials, different influences on the individual areas can occur and a counter-controlling of hot spots can take place. If the temperature is high in the area B1, the controlling gate voltage can be made smaller at the gate contacts 71.1 and 72.1. The same applies mutatis mutandis to other areas.

During operation, i.e. while the three gate voltages are applied, the temperature-dependent resistance of the measuring section is measured in each of the areas. A temperature for each of the areas can be computed from this. A temperature distribution results across the entire surface of the power component which consists of three concentric areas in the example of FIG. 6.

At least one pair of contact points is provided in each of the partial areas. These contacts points were explained above. The contact points are located on the gate electrode or the so-called gate electrode network of the respective partial area. Each of the contact points has a feed line and a contact, which makes it accessible in an electrically conductive fashion from the outside. The distance between one pair of contact points each is defined and unequivocal. An unequivocal measuring section, e.g. from the contact 81.3 to the contact 7 or from the contact 81.3 to the contact 82.3 is formed. Thus, an unequivocal measurement of the temperature-dependent resistance of the measuring section is possible, said temperature-dependent resistance enabling the determination of a temperature of a respective area during the operation of the component via the known temperature coefficient.

It should be mentioned that the measuring sections are distributed in such a way across the surface of the component that each measured resistance (in accordance with a specific temperature) corresponds to a surface portion of the total surface of the component. A temperature distribution through several existing temperature points or sites on the total surface of the component results.

The mentioned partial areas of the gate network or subsets of the individual cells 20 are unequivocally so different that there is no overlapping (in the case of a symmetrical distribution in both directions of the plane). Then an individual cell of the semiconductor power component only belongs to one of the several areas, in the example according to FIG. 6 only to one of the three areas B1, B2 and B3, which are represented there. Here, real subsets are concerned, and not overlapping subsets. The situation is different for designs of individual cells 20 which do not extend symmetrically in both directions of the plane, e.g. the structure of the elongated fingers according to FIG. 4. Here, this statement only applies in the transverse direction. Several independent gate electrodes may be provided in the longitudinal direction of the individual cells along an individual cell 20. According to FIG. 5 a respective individual cell has as many independently activating gate segments in the longitudinal direction as there are provided areas. The cells 20 at the outside left and outside right as paths 60 and 70 have e.g. only one gate, the central individual cell has three gates, which, however, are all independently activated and, for this purpose, are not electrically connected with each other. Differently activated individual cells 20 are formed in the longitudinal direction. Differently activated individual cells 20 are formed in the longitudinal direction. The several individual cells 20 are connected in parallel between drain 6 and source 5 for the power current, but can only be activated by one, two or several gate connections. A respective gate connection activates a group of individual cells or just one group of adjacent longitudinal sections of the individual cells inasmuch as they are located in the area of the gate electrode of the respective partial area with the appertaining gate voltage. The measuring voltage is superimposed on the gate voltage for each area.

The gate electrode sections in the partial areas B1 to B3 are measurable independently of each other and always remain measurable independently of each other. The gate electrodes in the partial area B1 with the contacts 71.1 and 72.1 permit a temperature detection in the partial area B1, which is independent e.g. of the partial areas B2 and B3, the entire area being detectable by measurement. Only the part 75 of the gate electrode of this area B2 is contacted for temperature measurement in the partial area B2.

The example shown in FIG. 5 distinguishes itself by the fact that the surface of the component is taken up by finger-shaped parallel individual cells and that the gate electrode network consists of strips located side by side or elongated annular paths.

For all methods or the power component (as an MOS component element) it may be a component of an integrated circuit (not shown) as described above. This integrated circuit can also include further circuit sections: an evaluation circuit (for evaluating the measuring value(s) from the temperature measuring section(s) and an activating circuit (for the control of the power supply of the component via the gate connections). This activation is effected automatically and dependent on the temperature detection and evaluation.

Transistor topologies are basically also possible, in particular in the case of individual transistors with vertical carrying of current, in which the active component surface is taken up by plurality of square or hexagonal individual cells. In this case the gate electrode network has the structure of a plate extending across the entire surface of the component, in which one recess each was implemented in the center of the periodically repeated basic cells. Here, as well, it is possible to measure the resistance of the gate electrode with the aid of additional gate electrode contacts and to thus determine the temperature of the component during the operation. Here, the additional contacts are advantageously arranged in a so-called Van-der-Pauw geometry at the periphery of a coherent network area, cf. Pauw et al., “Messung des spez. Widerstandes and des Hall-Koeffizienten an Scheiben beliebiger Form”, Philips Techn. Rundschau, No. 20, 230, 1959.

FIG. 7a is formed from FIG. 7 in a vertical section X-X of the uppermost row of the transistor or vice versa, the sectional plane Y-Y from FIG. 7a showing the top view, then in the form of a section of FIG. 7.

The current supply contacts 71.4 and 74.4 used for the resistance measurement and the contacts 73.4 and 72.4 for measuring the voltage of u₇ are disposed in the form shown in FIG. 7. If the representation in FIG. 7 relates to the entire surface of the component, only one statement averaged across the entire surface of the component during the resistance measurement is made.

It would be useful for the localized temperature detection of a distribution to subdivide the entire surface of the component into segments or areas, whose gate electrode networks are insulated from each other by suitable separating points. This is done in the same fashion as this is shown in FIG. 5 for the areas B1, B2, B3.

The representation of FIG. 7 corresponds to a four-point measurement as it was explained above by means of FIG. 3 with separate contacts for the current supply and separate contacts for the voltage measurement, said voltage being superimposed on the gate voltage during operation of the component of FIG. 7.

1. A method for measuring the operating temperature of an MOS semiconductor power component having a gate electrode (4) comprising a material with a temperature coefficient of an electrical resistance, thereof:
wherein the gate electrode (4) has two contact points (8, 9) disposed at a distance on the gate electrode (4), therebetween an unequivocal, electrically conductive measuring section (M1) is defined;
wherein the electrical resistance of the gate electrode (4) is directly measured at the gate electrode (4) during an operation of the MOS semiconductor power component with an applied gate voltage between the contact points (8, 9) by a measuring voltage (u₈₉) superimposed on the gate voltage (U_{G}); and
wherein a temperature of the MOS semiconductor power component is determined from the measured electrical resistance.

2. The method according to claim 1, wherein the gate electrode (4) is subdivided into several measuring sections with contact points (9, 11, 13, 15), which are in each case connected with strip conductors (10, 12, 14, 16) and wherein the contact points of each pair of contact points have a specific distance.

3. The method according to claim 1, wherein the measuring section is defined by the fact that at least one separation location (17) interrupts other conductive paths (4″) along the gate electrode for the electrical insulation of the measuring section.

4. The method according to claim 1, wherein a-c voltage is applied as the measuring voltage.

5. The method according to claim 1, wherein the MOS semiconductor power component comprises a discrete MOS power component.

6. The method according to claim 1, wherein the method is carried out without the presence of an additional temperature sensor.

6a. (canceled)

7. A method for the site-related electrical measurement of the operating temperature of an MOS semiconductor power component having a gate electrode network of a material and providing an electrical resistance, a temperature coefficient thereof being known:
wherein the gate electrode network is subdivided into several measuring sections with pairs of contact points which are in each case connected with contacts;
wherein the contact points of each pair of contact points have a specific distance and each of the measuring sections located between the pairs of contact points is in each case electrically insulated from the other measuring sections so that no electrical influence between the measuring sections is given;
wherein the electrical resistances of the measuring sections are directly measured at the gate electrode network during the operation of the MOS semiconductor power component with applied gate voltages between the contact points of the gate electrode (4) with measuring voltages (u₁, u₂, u₃) superimposed on the gate voltages; and
wherein the temperatures of the MOS semiconductor power component are determined from the electrical resistances of the measuring sections at the measuring sections.

8. The method according to claim 7, wherein the measuring sections are defined by the fact that separation locations interrupt other conductive paths along the gate electrode for the electrical insulation of the measuring sections.

9. The method according to claim 7, wherein a-c voltage is applied as the measuring voltage.

10. The method according to claim 7, wherein the MOS semiconductor power component comprises a plurality of individual cells with functionally the same structure.

11. The method according to claim 7, wherein the method is carried out without the presence of an additional temperature sensor.

12. The method according to claim 7, wherein the MOS semiconductor power component is a component of an integrated circuit and the temperature detection and evaluation of the temperature measuring section or temperature measuring sections and the power supply of the MOS semiconductor power component is automatically effected by a corresponding circuit as a component of the integrated circuit.

13. The method according to claim 7, wherein the pairs of contact points are distributed across the surface of a component in such a way that an allocation of temperatures to specific surface portions of the total surface of the component is given for a temperature distribution across the total surface of the component.

14. A MOS semiconductor power component for the electrical measurement of the temperature-dependent resistance of a gate electrode (4) for the purpose of the temperature control during the operation, wherein, in addition to a strip conductor (7) to a contact point (8) on the gate electrode (4), at least one additional contact is present at the gate electrode (4) at one additional contact point (9) of the gate electrode (4) of the MOS semiconductor power component so that a specific distance of the contact points (8, 9) on the gate electrode is determined and a measuring section is formed at the gate electrode (4) between contact point and contact point, the measuring section being insulated from other parts of the gate electrode (4).

15. The MOS semiconductor power component according to claim 14, wherein the gate electrode (4) is subdivided into several measuring sections with contact points that are respectively connected with conductor strips and wherein the contact points of each pair of contact points have a specific distance.

16. The MOS semiconductor power component according to claim 14, wherein the measuring section is defined by the fact that at least one separation location (17) interrupts other conductive paths along the gate electrode to electrically insulate the measuring section.

17. The MOS semiconductor power component according to claim 14, wherein the semiconductor power component comprises a discrete MOS power component.

18. A MOS semiconductor power component, which consists of a plurality of individual cells having functionally the same structure with a gate electrode network as the gate electrode (4) for the site-related electrical measurement of the temperature-dependent resistance during an active operation of the MOS semiconductor power component:
wherein several additional contact points forming pairs are present at the gate electrode network with contacts which are distributed to different partial areas (B1, B2, B3) of the gate electrode network as the gate electrode (4) of the MOS semiconductor power component; and
wherein the contact points of each pair of contact points have in each case a specific distance from each other, whereby a specific measuring section is defined in each case and the different defined measuring sections between the pairs of contact points are electrically insulated from each other by separation locations.

19. The MOS semiconductor power component according to claim 18, wherein several partial sections of the gate electrode (4), which are mutually electrically insulated, are present, which, in each case, have contacts attached to contact points at their ends.

20. The MOS semiconductor power component according to claim 18, wherein the measuring sections are distributed across the surface of the MOS semiconductor power component in such a way that an allocation of temperatures to specific surface portions of the total surface of the MOS semiconductor power component is given for measuring a temperature distribution.

20a. (canceled)

20b. (canceled)

21. A method for the measuring of temperature-dependent resistances of gate electrodes for a determination of a temperature distribution during the operation of a MOS semiconductor power component having a plurality of parallel individual cells having functionally the same structure, in which several ones of the plurality of individual cells together form in each case a partial area (B1, B2, B3) of the MOS semiconductor power component, wherein each partial area has a gate connection of its own which is common to the cells of the partial area as an area so that several areas with several gate connections are formed and gate electrodes of the partial areas (B1, B2, B3) are electrically insulated from each other by means of separation locations, wherein:
at least one pair of contact points (81.3, 82.3) on the gate electrode (4) of the partial area of the MOS semiconductor power component is present in each of the partial areas (B1, B2, B3) of the MOS semiconductor power component with appertaining feed lines and contacts (71.3, 72.3); and
the contact points of a pair of contact points have a specific distance from each other, whereby a measurement is carried out along an unequivocal measuring portion.

22. The method according to claim 21, wherein several measuring portions are distributed across a surface of the MOS semiconductor power component such that an allocation of specific temperatures to specific surface portions of the total surface of the MOS semiconductor power component is given.

23. The method according to claim 1, wherein the gate electrode is largely coupled to a subjacent silicon via a thin gate oxide so that the respectively measured temperature of the gate electrode of an area (B1, B2, B3) represents a good measure of the temperature of a subjacent silicon.

24. The method according to claim 21, wherein the plurality of individual cells form a real non-overlapping subset of the plurality for each of the partial areas as partial areas.

25. The method according to claim 21, wherein the electrically insulating separation locations extend transversely to a direction of extension of fingers (60, 61, 62) of the gate electrode (4).

26. The method according to claim 21, wherein a separation location separates a path of the gate electrode and provides electrically insulated ends on both sides of the separation location in order to fix the unequivocal separating section per partial area.

27. A MOS semiconductor power component having a plurality of parallel individual cells having functionally the same structure, wherein several partial areas (B1, B2, B3) of the MOS semiconductor power component are formed and each partial area as an area has a gate connection of its own which is common to the individual cells included in the partial area so that several areas with several gate connections are formed and gate electrodes of the partial areas (B1, B2, B3) are electrically insulated from each other by separation locations (17c, 17d; 17e, 17f) for the measurement of a temperature-dependent resistance of each of the gate electrodes during the operation of the MOS semiconductor power component for a determination of a temperature distribution, wherein:
at least one pair of contact points (81.3, 82.3) is present on the gate electrode (4) of the partial area of the MOS semiconductor power component in each of the partial areas (B1, B2, B3) of the MOS semiconductor power component and accessible from the outside in an electrically conductive fashion with appertaining feed lines and contacts; and
a respectively unequivocal measuring section is defined between the contact points of a respective pair of contact points for measuring a temperature-dependent resistance.

28. The MOS semiconductor power component according to claim 27, wherein the several individual cells (20) between drain (6) and source (5) are connected in parallel, but can be activated by at least one gate connection, wherein a respective gate connection activates the individual cells or longitudinal sections of the individual cells (20) in the area of the gate electrode of the respective partial area.

29. The MOS semiconductor power component according to claim 27, wherein the electrically insulating separation locations (17c, 17d) extend transversely to a direction of extension of fingers (60, 61, 62) of the gate electrodes (4).

30. The MOS semiconductor power component according to claim 27, wherein a separation location (17a, 17b) separates a path of a gate electrode and provides electrically insulated ends on both sides of the separation location in order to fix the unequivocal measuring section per partial area.

31. The MOS semiconductor power component according to claim 27 or 30, wherein an operation of the MOS semiconductor power component includes an activation of the gate electrodes of the partial areas (B1, B2, B3) with a voltage for switching the MOS semiconductor power component.

32. The MOS semiconductor power component according to claim 27, wherein the activation of each gate electrode of each partial area (B1, B2, B3) takes place independently or the gate electrodes of the partial areas (B1, B2, B3) are independently activated.

33. The method according to claim 1, wherein the electrical resistance of a portion (4′) of the gate electrode (4) is measured.

34. The MOS semiconductor power component according to claim 18, having several gate connections (7, 71.1, 71.2) and one gate connection each is allocated to a partial area (B1, B2, B3).

35. The MOS semiconductor power component according to claim 34, wherein the several gate connections are not electrically connected.
